(19) United States
(12) Patent Application Publication
(10) Pub. No.: US 2026/0094334 A1
(43) Pub. Date: Apr. 2, 2026

(54) DEEP UNROLLED MODEL FOR ACCELERATED IMAGE RECONSTRUCTION

(71) Applicant: Rutgers, The State University of New Jersey, New Brunswick, NJ (US)

(72) Inventors: Dimitris N. Metaxas, Princeton, NJ (US); Bingyu Xin, New Brunswick, NJ (US); Meng Ye, New Brunswick, NJ (US)

(21) Appl. No.: 19/347,386

(22) Filed: Oct. 1, 2025

Related U.S. Application Data
(60) Provisional application No. 63/702,006, filed on Oct. 1, 2024.

(51) Int. Cl. G06T 11/00; G01R 33/56

(52) U.S. Cl. CPC G06T 12/20; G01R 33/5608; G06T 2210/41; G06T 2211/424; G06T 2211/441

(57) ABSTRACT

Systems, methods, and apparatuses for image reconstruction. One computer-implemented method includes receiving measurement data representing a subject and generating an image estimate of the subject based on the measurement data. The method also includes refining the image estimate by performing an iterative reconstruction process comprising a plurality of iteration steps, each iteration step comprising (i) computing a data consistency term based on the image estimate and the measurement data, (ii) generating a correction term using a machine learning model based on the image estimate, the data consistency term, the measurement data, and cross-iteration information, and (iii) updating the image estimate based on the correction term, the data consistency term, and a global learning rate corresponding to the iteration step.

### RELATED APPLICATIONS

This application claims priority to U.S. Provisional Application No. 63/702,006, filed Oct. 1, 2024, the entire content of which is incorporated herein by reference.

### STATEMENT REGARDING FEDERALLY SPONSORED RESEARCH OR DEVELOPMENT

This invention was made with government support under grant number FA9550-23-1-0417 awarded by the Department of Defense, grant number HL127661 awarded by the National Institutes of Health and grant numbers 2310966, 2235405, 2212301, and 2003874 awarded by the National Science Foundation. The government has certain rights in the invention.

### FIELD

The present disclosure relates to deep learning models for performing image reconstruction, such as, for examples, a deep unrolled model for performing Magnetic Resonance Imaging (MRI) reconstruction.

### SUMMARY

Magnetic Resonance Imaging (MRI) is a widely used imaging modality for clinical diagnostics and the planning of surgical interventions. Accelerated MRI seeks to mitigate the inherent limitation of long scanning time by reducing the amount of raw k-space data required for image reconstruction.

Examples described herein provide a deep unrolled model (DUM) for accelerated image reconstruction, such as, for example, Magnetic Resonance Image (MRI) reconstruction. By improving gradient and information flow across iteration stages in the DUM, the proposed technique improves reconstruction quality. By using adjacent reconstruction, including adjacent multi-coil sensitivity map estimation as described herein, the reconstruction performance is improved and memory (e.g., graphics processing unit (GPU) memory) consumption (e.g., during model training and testing and inference) is reduced. For example, the methods and systems described herein address limitations in traditional deep unrolled models, such as limited transmission capacity and inefficiencies in sensitivity map estimation.

For example, the methods and systems described herein provide one or more of the following technological improvements (i) enhance the gradient and information flow within and across iteration stages of a DUM, (ii) use various adjacent information for accurate and memory-efficient sensitivity map estimation, and (iii) improved multi-coil MRI reconstruction. It should be understood that these improvements may be used individuals or in various combinations.

According to some examples, a computer-implemented method is provided that includes receiving measurement data representing a subject; generating an image estimate of the subject based on the measurement data; and refining the image estimate by performing an iterative reconstruction process comprising a plurality of iteration steps, each iteration step including computing a data consistency term based on the image estimate and the measurement data; generating a correction term using a machine learning model based on the image estimate, the data consistency term, the measurement data, and cross-iteration information; and updating the image estimate based on the correction term, the data consistency term, and a global learning rate corresponding to the iteration step.

According to some examples, a computer-implemented method for momentum-accelerated image reconstruction using a multi-level neural network including an encoder and a decoder is provided that includes, for each iteration step, at each level of the decoder, concatenating image features from the iteration step with image features from previous iteration steps at the level to obtain a plurality of concatenated features; generating a combined feature based on the plurality of concatenated features and a set of attention weights, the set of attention weights obtained using an attention mechanism based on the plurality of concatenated features; and iteratively reconstructing the image by updating an image estimate at the iteration step based on the combined features.

According to some examples, a computer-implemented method for memory-efficient sensitivity map estimation for multi-coil image reconstruction is provided that includes receiving measurement data corresponding to a plurality of image slices of a subject; extracting auto-calibration signal (ACS) data from the measurement data for a group of adjacent image slices, the group of adjacent image slices including a target slice and at least one neighboring slice; and generating, via a single forward pass of the extracted ACS data through a sensitivity map estimation network, a sensitivity map set for the group of adjacent image slices, wherein the sensitivity map set is a concatenation of sensitivity maps for the target slice and the at least one neighboring slice.

Other examples, features, and aspects will become apparent by consideration of the detailed description and accompanying appendices.

### BRIEF DESCRIPTION OF THE DRAWINGS

FIG. 1A illustrates memory consumption for training and testing using methods and systems described herein as compared to another technique.

FIG. 1B illustrates image quality metrics versus a number of parameters using the methods and systems described herein as compared to other techniques.

FIG. 2A schematically illustrates a self-adaptive gradient algorithm according to some examples.

FIG. 2B schematically illustrates a momentum-accelerated gradient algorithm according to some examples.

FIG. 3 schematically illustrates a deep unrolled model implementing the gradient algorithms of FIGS. 2A and 2B according to some examples.

FIG. 4 schematically illustrates a denoiser used in the deep unrolled model of FIG. 3 according to some examples.

FIG. 5 is a visualization of adaptively learned auxiliary memory according to some examples.

FIG. 6 is a graph comparing training losses using different iterative updating equations.

FIG. 7 is a visualization of the feature maps learned by the denoiser at different levels across iterations according to some examples.

FIG. 8A illustrates how sensitivity maps exhibit variations across time according to some examples.

FIG. 8B illustrates how sensitivity maps exhibit variations across contrast according to some examples.

FIG. 8C illustrates how sensitivity maps exhibit variations across slice dimension according to some examples.

FIGS. 9A, 9B, 9C, and 9D conceptually illustrate different strategies for multi-coil sensitivity map estimation (SME) according to some examples.

FIG. 10 illustrates reconstruction results and error maps of various reconstruction methods for the Calgary-Campinas brain imaging under ×10 acceleration factor.

FIG. 11 illustrates reconstruction results and error maps of various reconstruction methods for the CM-RxRecon cardiac T1-weighted imaging under ×10 acceleration factor.

FIG. 12 illustrates the reconstruction results and SSIM error maps of various reconstruction methods for the fastMRI multi-coil knee proton density (PD) imaging under ×8 acceleration.

FIGS. 13A, 13B, 13C, and 13D provide a comparison of the systems and methods described herein with PromptMR on the convergence speed of iterations in a DUM for MRI reconstruction.

FIG. 14 schematically illustrates a computing system configured to perform the functionality described herein according to some examples.

FIG. 15 is a flowchart illustrating a computer-implemented method for performing image reconstruction according to some examples.

FIG. 16 is a flowchart illustrating a computer-implemented method for performing image reconstruction according to some examples.

FIG. 17 is a flowchart illustrating a computer-implemented method for performing image reconstruction according to some examples.

FIGS. 18-24 include various tables representing performance of methods and systems described herein or components thereof according to some examples.

### DETAILED DESCRIPTION

As noted above, Magnetic Resonance Imaging (MRI) provides a radiation-free and highly versatile method for imaging the organs, tissues, and skeletal systems within the human body. Over the years, MRI has evolved to become a cornerstone in clinical diagnostics. However, the process of raw k-space data acquisition in MRI is typically time-consuming. Accelerated MRI techniques tackle this issue by minimizing the amount of raw data that needs to be collected for image reconstruction, thereby shortening the duration of the scan. Modern advances in MRI technology, including Parallel Imaging (PI) and Compressed Sensing (CS), have significantly enhanced the efficiency and quality of MRI scans, making it possible to acquire high-resolution images within a considerably reduced time frame. However, with increased patient throughput and the requirements of emerging technologies, such as real-time MRI and low-field MRI, there remains a need for the development of accelerated MRI reconstruction methods.

Accelerated MRI reconstruction is a regularized inverse problem, which aims to reconstruct an unknown MR image from highly undersampled measurements in k-space. Conventional iterative MRI reconstruction methods minimize a cost function comprising two main components: a data-consistency term, which assesses the alignment between k-space predicted from the reconstructed image and the observed measurements, and a regularization term, which incorporates prior knowledge to encourage the emergence of desirable image attributes, e.g., sparsity.

Deep learning has also been applied to MRI construction, including, for example, several large-scale public MRI reconstruction benchmarks, including the fastMRI dataset, Calgary-Campinas dataset, and CMRxRecon dataset, which has propelled the advancement of MRI reconstruction methods. Among deep learning-based MRI reconstruction approaches, the deep unrolled model (DUM), which maps a truncated optimization algorithm into a deep neural network, iteratively alternating between gradient descent steps and proximal mapping steps, provides improved performance and the ability to establish a concrete and systematic link between widely used iterative MRI reconstruction methods and deep neural networks.

However, the current architecture design of DUM is inefficient, characterized by limited information transmission capacity and low flexibility and robustness. These shortcomings significantly restrict DUM's performance and its applicability to unseen data. For example, many existing methods underscore the advantages of introducing additional priors into the input at each iteration stage, aiming to dismantle the information bottlenecked encountered within each iteration. Additionally, when reconstruction methods focus exclusively on synthesized single-coil k-space data, the methods overlook the more prevalent multi-coil imaging in real clinical MRI scans. This oversight neglects a more realistic scenario, given the widespread application of parallel imaging. Parallel imaging (PI) can speed up MRI, with the idea of using multiple receiving coils to reduce the number of phase encoding lines needed in acquiring raw k-space data. The sensitivity map of a given coil is its local field profile, describing through reciprocity where that coil can efficiently pick up MR signals from the imaged region. The reconstruction of multiple coil k-space data needs accurate estimation of the sensitivity maps, which are either directly measured or indirectly accounted using a center region of k-space data.

Accordingly, examples described herein address these other technologies issues and deficiencies by, for example, providing one or more of the following:

(a) Improving the adaptive gradient algorithm and applying it to DUM, which can achieve self-adaptive dynamic learning rates adjusting for different spatial areas in an MR image. This approach provides a more flexible updating strategy in each iteration stage of DUM (see, e.g., Section II below).

(b) Incorporating the momentum technique used in gradient descent acceleration and a multi-stage and multi-level feature aggregation scheme to accelerate the iteration convergence of DUM (see, e.g., Section III below).

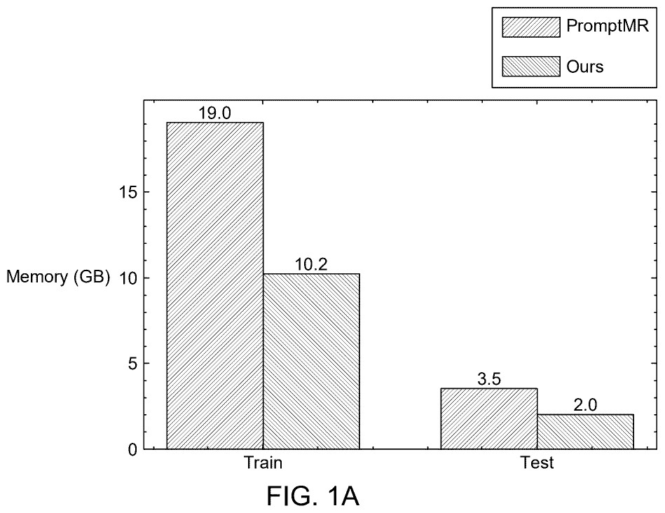

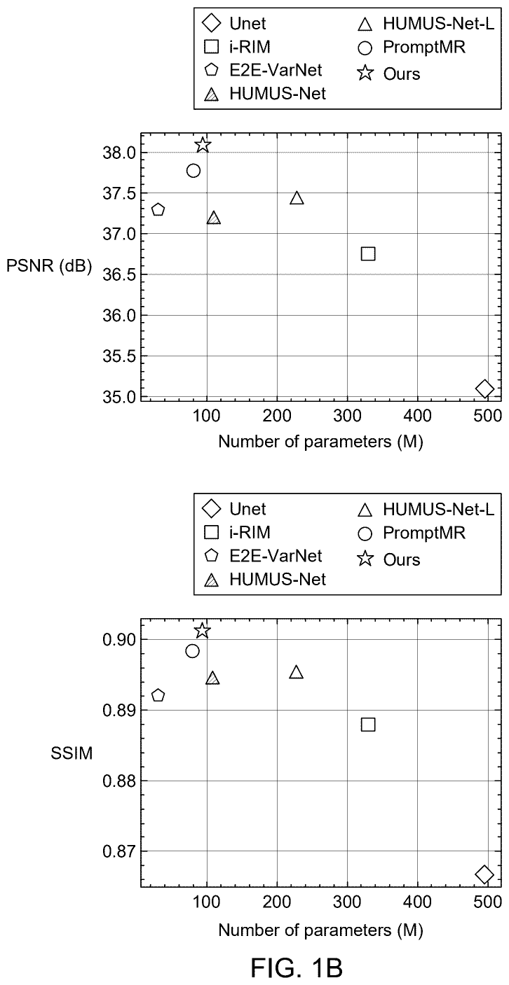

(c) Improving multi-coil MRI reconstruction using adjacent information and, in particular, performing accurate and memory efficient sensitivity map estimation. For example, as shown in FIG. 1A, the methods and systems described herein (referenced as “Ours” in the FIG. 1A) reduces processing unit (e.g., graphics processing unit (GPU)) memory consumption approximately 55% as compared to other techniques (e.g., PromptMR) (e.g., using the Calgary-Campinas brain dataset) (see, e.g., Section IV below).

(d) Improve effectiveness and performance of image reconstruction. For example, as described herein and illustrated in FIG. 1B, the methods and systems described herein (referenced as “Ours” in FIG. 1B) achieve a better Peak Signal-to-Noise Ratio (PSNR) and Structural Similarity Index Measure (SSIM) with fewer parameters than existing MRI reconstruction methods used with public MRI reconstruction benchmarks of different anatomies (e.g., the fastMRI knee, the Calgary-Campinas brain, and the CMRxRecon cardiac dataset) (see, e.g., Section V below).

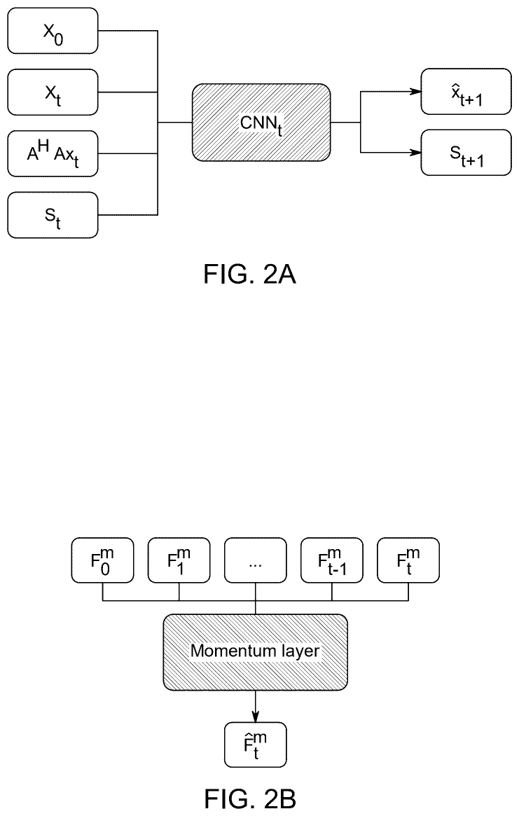

For example, FIG. 2A schematically illustrates a self-adaptive gradient algorithm and FIG. 2B schematically illustrates a momentum-accelerated gradient algorithm used by the methods and systems described here to perform image reconstruction (e.g., MRI reconstruction) according to some examples. As described herein, this algorithm dynamically incorporates prior knowledge in the data flow, to enable more informative and faster convergence for gradient-based MRI reconstruction learning.

### I. Deep Unrolled Model

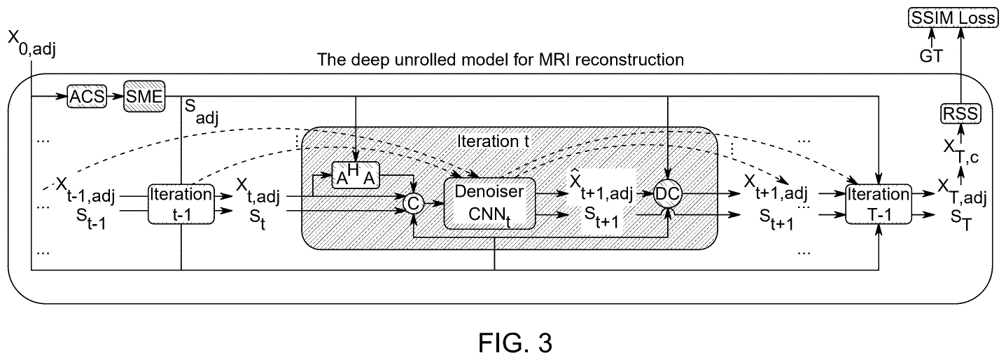

A DUM used to implement the algorithms in FIGS. 2A and 2B is schematically illustrated in FIG. 3. In FIG. 3, the structure depicted in iteration t implements the deep unrolling of Equation (7) below. The dashed lines in FIG. 3 depict the multi-stage and multi-level information flow. It should be understood that the illustration in FIG. 3 is simplified by presenting the flow only for the t-th iteration.

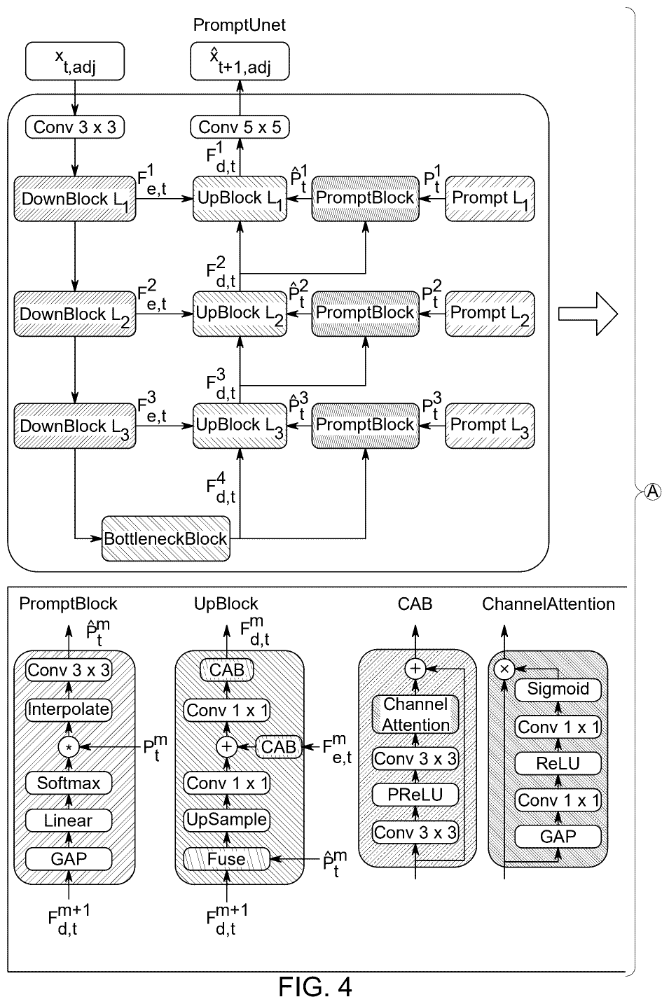

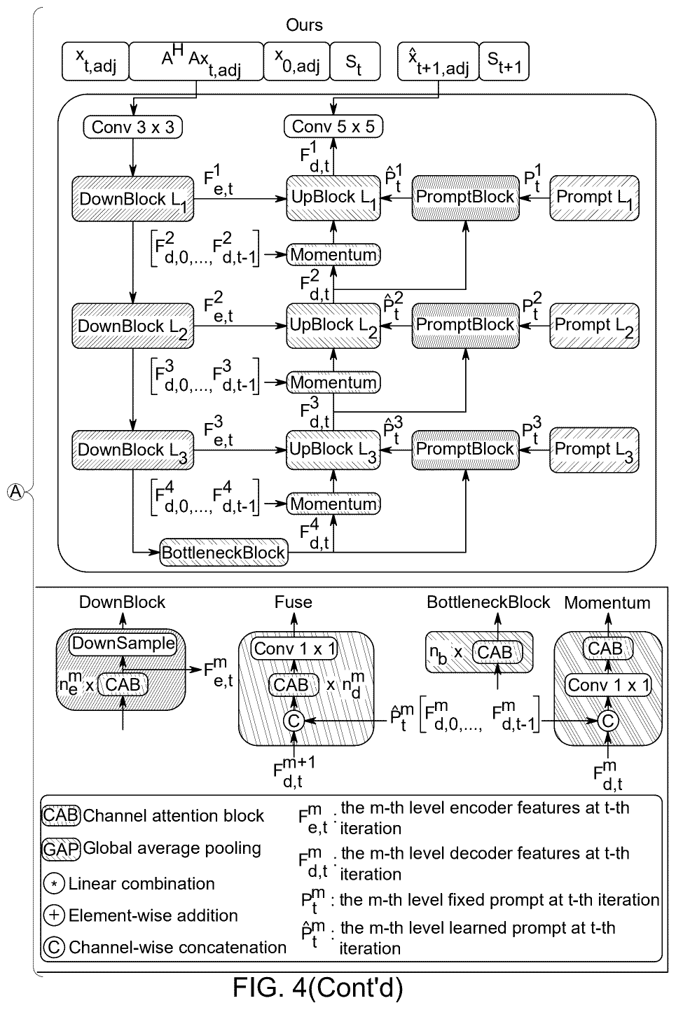

In some implementations, the architecture illustrated in FIG. 3 is built upon PromptMR, but the architecture may be built upon other models for multi-coil accelerated MRI reconstruction. As described herein, as compared to PromptMR the architecture illustrated in FIG. 3 provides, among other things, a novel design of the denoiser in each iteration and the multi-coil sensitivity map estimation strategy. In particular, for the design of the denoiser, the PromptUnet in Prompt MR is enhanced with the self-adaptive gradient algorithm and the momentum layer, as illustrated in FIG. 4.

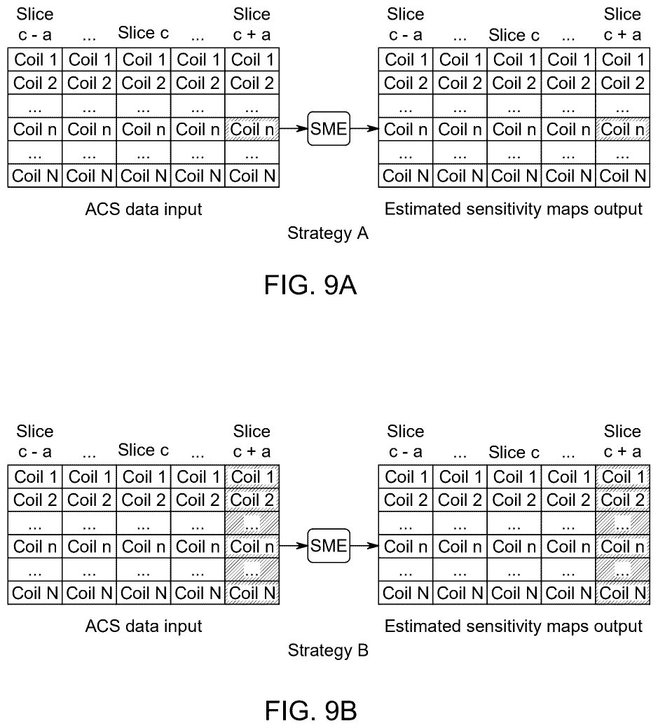

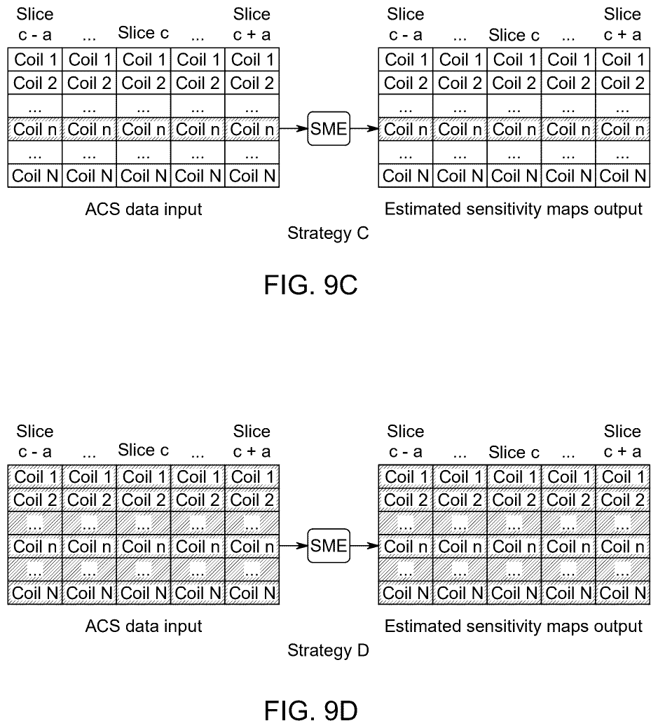

The reparameterization of the later term in Equation (6) described herein results in a different input and output of the PromptUnet compared with PromptMR. In this architecture, the auxiliary memory sₜ is initialized as s₀=x_{0, adj}. For the multi-coil sensitivity map estimation (SME), the architecture transitions from the coil-by-coil estimation in PromptMR (see strategy A in FIG. 9A) to an adjacent coil estimation strategy (see strategy C in FIG. 9C). For example, in PromptMR, the SME network's input/output channels are set to 2 to account for the complex tensor nature of the sensitivity maps, with the real and imaginary parts concatenated. In the architecture described herein, the number of input/output channels are adjusted to 2(2a+1), where 2a+1 represents the number of adjacent slices. This modification allows the network to leverage information from neighboring slices during the estimation process.

In some examples, the total number of model iterations, T, is set to 12 and the adjacent number is set to 2a+1=5 (i.e., a=2). In some examples, no data augmentation method is employed but an optimizer (e.g., AdamW with a weight decay of 0.01) may be used. Also, in some examples, the SSIM loss between the central slice x_{T,c} of the reconstructed output x_{T,adj} and the ground truth x_{GT} was minimized as set forth in Equation (12) below:

$${L}_{SSIM} = 1 - SSIM ( {x}_{T , c} , {x}_{GT} ) \qquad ( 12 )$$

Returning to FIGS. 2A and 2B and to formulate the problem, a complex MR image x can be estimated from its undersampled measurements y in k-space by solving an optimization problem according to Equation (1) below:

$${min}_{x} f ( x ) = {min}_{x} \frac{1}{2} ‖ Ax - y ‖ \frac{2}{2} + R ( x ) \qquad ( 1 )$$

Where A=MFS is the forward process of acquiring k-space measurements, which is a combination of coil sensitivity maps S, the Fourier transform F, and an undersampling mask M. the first term

$$( \frac{1}{2} ‖ Ax - y ‖ \frac{2}{2} )$$

represents the data consistency term, which ensures data fidelity, while the second term R(x) serves as the regularization term, aimed at promoting image domain priors, such as sparsity. Equation (1), therefore, can be solved iteratively via the gradient descent method set forth below in Equations (2) and (3):

$${x}_{t + 1} = {x}_{t} - {η}_{t} {g}_{t} \qquad ( 2 )$$

$${g}_{t} = {A}^{H} ( {Ax}_{t} - y ) + ∇ R ( {x}_{t} ) \qquad ( 3 )$$

Where ∇R(xₜ) is the gradient or the proximal mapping R, ηₜ is the scaler learning rate at iteration t, and t∈{0, 1, . . . , T−1}, with T being the total number of truncated iterations. In the context of deep unrolled models, ∇R(xₜ) can be substituted with a neural network (e.g., a convolutional neural network CNN) whose parameters are learned from large-scale training datasets. This allows for the learning of more sophisticated image domain priors, compared to those that are hand-crafted.

### II. Self-Adaptive Gradient Algorithm

During the iterative MRI reconstruction process, some regions in an image are straightforward to reconstruct, such as the background, which contains minimal information. However, other areas are more prone to aliasing artifacts resulting from downsampling the k-space, which are challenging to eliminate. This difficulty often arises because the aliasing artifacts may closely mimic the appearance of anatomical structures within these regions, necessitating a more meticulous gradient-based correction at each iteration. Accordingly, to address this and other technological issues, self-adaptive learning rates for individual pixels can be used instead of applying a uniform learning rate across the entire image space at each iteration. For example, the methods and systems described generalize the standard gradient descent in Equation (2) employing the following update for each iteration:

$${x}_{t + 1} = {x}_{t} - {η}_{t} {g}_{t} - {E}_{t} ⊙ {g}_{t} \qquad ( 4 )$$

$${E}_{t} = \frac{{η}_{t}}{\sqrt{{\sum }_{τ = 0}^{t} {g}_{τ}^{2} + ∈}} - {η}_{t} \qquad ( 5 )$$

Where Eₜ is the residual pixel-wise learning rate at the t-th iteration, and the denominator in Equation (5) computes the root of the sum of squares of all previous gradients of individual pixels. E is a small number to improve the numerical stability. The operation ⊙ denotes element-wise multiplication. The accumulation of historical pixel-wise gradients in Equation (5) helps improve iteration convergence by: (1) scaling down the updating steps for regions with historically large gradients, which may be prone to overshooting, and (2) scaling up the updating steps for regions with historically small gradients, which may benefit from a more aggressive update.

To unroll the above-described self-adaptive gradient algorithm with a DUM, the methods and systems described herein may not substitute ∇R(xₜ) with a neural network in Equation (4) (as performed for other techniques). For example, learning the ∇R(xₜ) term in gₜ (see Equation (3)) can lead to numerical instability in Eₜ during the early stage of training. In addition, the adaptive gradient strategy in Equation (5), may not be the most suitable choice for a DUM in the context of MRI reconstruction. Accordingly, to leverage the robust nonlinear representation capabilities of neural networks, the adaptive gradient algorithm is improved by reformulating Equation (4) as follows:

$$\begin{matrix}{x}_{t + 1} & = & {x}_{t} - {η}_{t} {A}^{H} ( {Ax}_{t} - y ) - ( {η}_{t} ∇ R ( {x}_{t} ) + {E}_{t} ⊙ {g}_{t} ) & ( 6 ) \\ & = & {x}_{t} - {η}_{t} {A}^{H} ( {Ax}_{t} - y ) + {CNN}_{t} ( {x}_{t} , {A}^{H} {Ax}_{t} , {A}^{H} y , {s}_{t} ) & ( 7 ) \\ & & & \end{matrix}$$

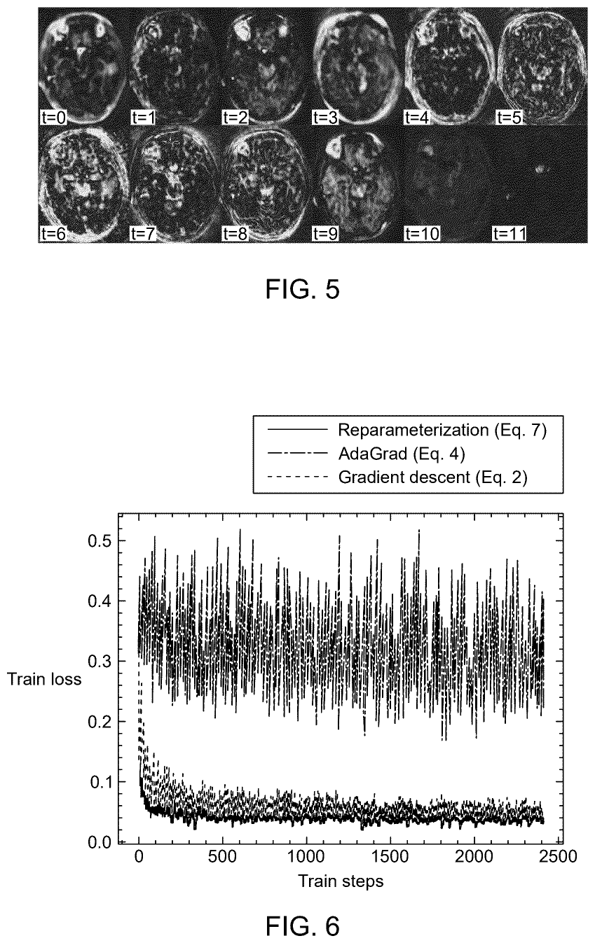

The last term in Equation (6) is reparametrized with a CNN, as indicated in Equation (7). This neural network takes as input the fundamental components from which the term is constructed, namely, xₜ, A^{H}Aₓₜ, A^{H}y, and a learnable auxiliary memory sₜ, which serves as a hidden state to track the historical gradient information implicitly. For example, FIG. 5 provides a visualization of the adaptively learned auxiliary memory sₜ. As illustrated in FIG. 5, at each iteration, the sₜ learns the historical gradient information. Note that A^{H}y yields x₀, which represents the image transformed from zero-filled k-space.

For example, with respect to the reparameterization, when the learned gₜ is very large, the adaptive learning rate Eₜ+ηₜ after stage t will be close to 0. As a result, the reconstruction improvement in DUM may get stuck during training, as shown in FIG. 6. Similarly, there are many variants of adaptive gradient methods, but a CNN can provide more flexibility and is more powerful than hand-crafted variants.

To reparameterize the last term in Equation 6 using a CNN in Equation (7), the last term in Equation 6 (denoted as LHS) can be written as follows:

$$LHS = - \{ {η}_{t} ∇ R ( {x}_{t} ) + ( \frac{{η}_{t}}{\sqrt{{\sum }_{τ = 0}^{t} {g}_{τ}^{2} + ∈}} - {η}_{t} ) ⊙ {g}_{t} \}$$

As LHS is being reparameterized to a network, the scalar multiplier—ηₜ can be readily learned and is therefore omitted here for simplicity. Accordingly, a CNNₐ can be used to the image prior ∇R in the first term and, concurrently, a CNNₐ can be used to learn a more advanced version of the second term, which is related to the current gradient gₜ and the historical gradients {gₜ−1, . . . , g₁, g₀},

$$\begin{matrix}LHS = ∇ R ( {x}_{t} ) + ( \frac{1}{\sqrt{{\sum }_{τ = 0}^{t} {g}_{τ}^{2} + ∈}} - 1 ) ⊙ {g}_{t} \\ = {CNN}_{a} ( {x}_{t} ) + {CNN}_{b} ( {g}_{t} , {g}_{t - 1} , ... , {g}_{1} , {g}_{0} ) ⊙ {g}_{t} \\ = {CNN}_{a} ( {x}_{t} ) + {CNN}_{c} ( {g}_{t} , {s}_{t} ) ⊙ {g}_{t} \\ = {CNN}_{a} ( {x}_{t} ) + {CNN}_{d} ( {g}_{t} , {s}_{t} )\end{matrix}$$

Where we implicitly use auxiliary memory sₜ to learn the historical gradients. Note that per Equation (3):

$$\begin{matrix}{g}_{t} = {A}^{H} {Ax}_{t} - {A}^{H} y + ∇ R ( {x}_{t} ) \\ = {A}^{H} {Ax}_{t} - {A}^{H} y + {CNN}_{a} ( {x}_{t} )\end{matrix}$$

Substituting this formula into LHS yields:

$$LHS = {CNN}_{a} ( {x}_{t} ) + {CNN}_{d} ( {A}^{H} A {x}_{t} - {A}^{H} y + {CNN}_{a} ( {x}_{t} ) , {s}_{t} )$$

The updating formulation of Equation (6) of the adaptive gradient method can also be written as:

$${x}_{t + 1} = {x}_{t} - {η}_{t} {A}^{H} ( {Ax}_{t} - y ) + {CNN}_{a} ( {x}_{t} ) + {CNN}_{d} ( {A}^{H} {Ax}_{t} - {A}^{H} y + {CNN}_{a} ( {x}_{t} ) , {s}_{t} )$$

Although an additional network CNN_{d} is used, to minimize changes to the existing framework, the two networks can be combined into one by further processing the LHS as follows:

$$\begin{matrix}LHS = {CNN}_{a} ( {x}_{t} ) + {CNN}_{e} ( {A}^{H} {Ax}_{t} - {A}^{H} y , {CNN}_{a} ( {x}_{t} ) , {s}_{t} ) \\ = {CNN}_{f} ( {A}^{H} {Ax}_{t} - {A}^{H} y , {CNN}_{a} ( {x}_{t} ) , {s}_{t} ) \\ = {CNN}_{t} ( {A}^{H} {Ax}_{t} - {A}^{H} y , {x}_{t} , {s}_{t} )\end{matrix}$$

Thus, the updating formulation used by the methods and systems described herein can be represented as:

$${x}_{t + 1} = {x}_{t} - {η}_{t} {A}^{H} ( {Ax}_{t} - y ) + {CNN}_{t} ( {A}^{H} {Ax}_{t} - {A}^{H} y , {x}_{t} , {s}_{t} )$$

Where the soft data-consistency term A^{H}Axₜ−A^{H}y reflects the degree to which the current estimate xₜ is consistent with the measured data y under the forward model A. In other words, the more generalized updating formulation can be as follows:

$${x}_{t + 1} = {x}_{t} - {η}_{t} {A}^{H} ( {Ax}_{t} - y ) + {CNN}_{t} ( {A}^{H} A {x}_{t} , {A}^{H} y , {x}_{t} , {s}_{t} )$$

Unlike other deep unrolled models, where the denoiser only learns the image prior as CNNₐ, the denoiser CNNₜ is also coupled with the iteration progress sₜ and degradation model A, leading to more meticulous gradient-based learning.

### III. Momentum-Accelerated Gradient Algorithm

The momentum method described herein accelerates gradient descent in Equation (2) by accumulating a velocity vector in directions of persistent reduction in the optimization objective across iterations:

$${x}_{t + 1} = {x}_{t} - {η}_{t} {m}_{t} \qquad ( 8 )$$

$${m}_{t} = μ {m}_{t - 1} + ( 1 - μ ) {g}_{t} \qquad ( 9 )$$

Where μ∈[0, 1] is the momentum coefficient. The momentum mₜ is known as the exponential moving average of historical gradients. It can benefit the optimization of the current iteration, thereby considerably accelerating convergence.

As described above, the hidden state sₜ is used to implicitly track the pixel-wise historical gradient information. For the momentum method, explicit multi-stage and multi-level feature aggregation is performed, to mimic the idea of momentum and increase the information flow across the iterations.

For example, for a typical multi-level encoder-decoder denoiser, such as Unet, in the t-th iteration, a momentum layer can be inserted before the m-th level decoder layer. This layer concatenates features at the current stage and features from all previous iteration stages at the same level, followed by a 1×1 convolution layer to reduce the dimensionality, and a Channel Attention Block (CAB) to adaptively fuse the multi-stage information, as described below:

$$Momentum ( {F}_{0}^{m} , … , {F}_{t}^{m} ) = CAB ( {Conv}_{1 x1} ( Concat ( {F}_{0}^{m} , … , {F}_{t}^{m} ) ) ) Where {F}_{t}^{m} \qquad ( 10 )$$

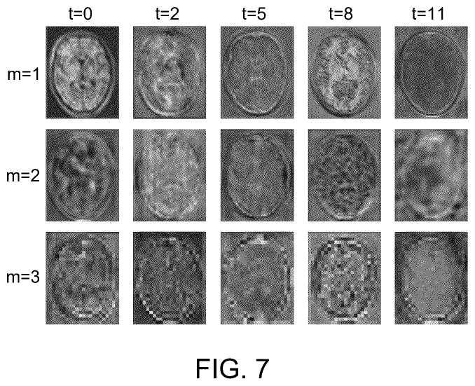

is the input feature of the m-th level decoder layer at the t-th iteration. FIG. 7 provides a visualization of the feature maps

$${F}_{t}^{m}$$

learned by the denoiser at different levels m across iterations t.

### IV. Adjacent Reconstruction

As noted above, a limitation of adjacent slice reconstruction lies in its substantial memory consumption during the estimation of multi-coil sensitivity maps. This issue stems from the design of the existing sensitivity map estimation (SME) network. This existing network adopts a coil-by-coil estimation approach to accommodate a variable number of coils, increasing flexibility but leading to higher memory demands in the adjacent reconstruction setting (see FIG. 4). To be more specific, for k-space data with N coils and 2a+1 adjacent slices, the total number of forward passes required for the SME process is calculated as (2a+1) N. Typically, the value of N ranges from 8 to 34 and a is set to 2.

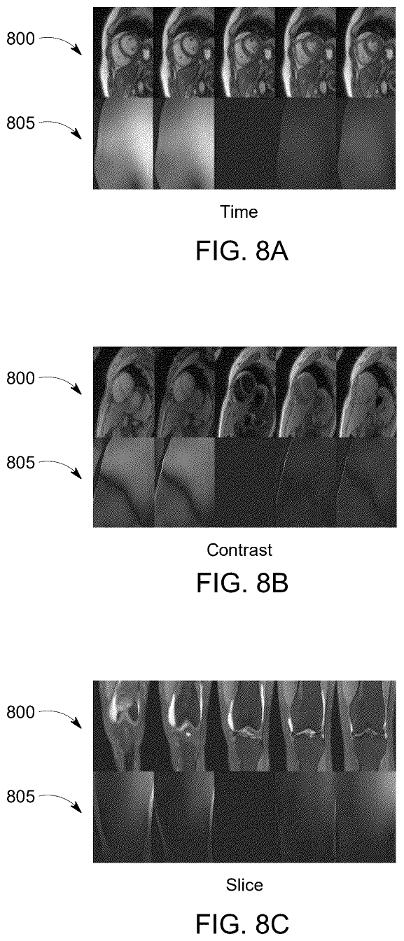

Examples described herein may provide adjacent slice reconstruction that reduces the number of forward passes by utilizing the correlations between adjacent sensitivity maps. A sensitivity map is subject to variation, based on the position of the imaging subject and changes over time due to the subject motion. Additionally, in multi-contrast MRI acquisition, variations in acquisition parameters, such as inversion time (TI) and repetition time (TR), can indirectly influence the sensitivity map estimation through the acquired k-space data, as shown in FIGS. 8A, 8B, and 8C. For example, FIG. 8A illustrates how sensitivity maps exhibit variations across time, FIG. 8B illustrates how sensitivity maps exhibit variations across contrast, and FIG. 8C illustrates how sensitivity maps exhibit variations across slice dimension. The first row 800 in FIGS. 8A, 8B, and 8C includes original images, and the second row 805 in FIGS. 8A, 8B, and 8C represents a magnitude of differences between the sensitivity map of the central image and each of those of its adjacent images.

Consequently, the estimation of adjacent sensitivity maps is a spatially, temporally, and contrastively correlated process. Accordingly, the methods and systems described herein may estimate sensitivity maps by utilizing information from spatially, temporally, and contrastively adjacent slices. For example, as shown in FIG. 9C, a single coil sensitivity map at all adjacent 2a+1 slices is simultaneously estimated using information across these slices. In this way, the number of forward passes is reduced from (2a+1) N to N. For example, FIGS. 9A, 9B, 9C, and 9D conceptually illustrate different strategies for multi-coil sensitivity map estimation (SME). One difference between the four strategies lies in the Auto-Calibration Signal (ACS) information sharing between coils and adjacent MR image slices. For example, each single coil sensitivity map gets ACS information from (a) a single coil and a single image slice, (b) multiple coils but not a single image slice; (c) a single coil but multiple adjacent image slices; or (d) multiple coils and multiple adjacent image slices. In such examples, the estimation of the n-th sensitivity map set

$${S}_{adj}^{n}$$

can be described as:

$${S}_{adj}^{n} = SME ( ACS ( {x}_{0 , adj}^{n} ) ) \\ Where {S}_{adj}^{n} = [ {S}_{c - a}^{n} , … , {S}_{c}^{n} , … , {S}_{c + a}^{n} ] \qquad ( 11 )$$

is an adjacent sensitivity map set that is the concatenation of central slice sensitivity map

$${S}_{c}^{n}$$

with its 2a-adjacent slice sensitivity maps of the n-th coil, and

$$ACS ( {x}_{0 , adj}^{n} )$$

is the n-th coil Auto-Calibration Signal (ACS) within all adjacent 2a+1 slices. In some examples, the ACSs are part of the acquired central k-space data.

### V. Experiments and Results

As noted above, the methods and systems described here provide improved reconstruction performance as compared to existing techniques. For example, experimental results are presented below for the methods and systems as described herein used across multiple publicly available datasets, including the Calgary-Campinas brain dataset, the CMRxRecon cardiac dataset, and the fastMRI multi-coil knee dataset. These datasets encompass a diverse range of anatomies, contrasts, views, slices and motion states. The setups and configurations for these experiments are described below. However, it should be understood that other setups and configurations are possible for use with the methods and systems described herein and, thus, the experiment setups described herein should not be construed as limiting.

For the Calgary-Campinas brain experiment, the data split setting used in Recurrent-VarNet was used, where the number of training, validation, and test cases is 47, 10, and 10, respectively. Since each case contains 256 slices, the number of training, validation, and test slices is 12032, 2560, 2560. This experiment also used the Poisson-disc sampling mask, as provided by the official Calgary-Campinas challenge, with acceleration factors of ×5 and ×10 during training. The center of the k-space was fully sampled within a radius of 16. The evaluation was conducted using the code in the official Calgary-Campinas challenge repository4, where the first and last 50 slices in each volume were excluded from the evaluation since little meaningful anatomy were presented. The model was trained for 19 epochs with a learning rate of 0.0001, dropped by a factor of 10 at the last epoch. Training took 17 hours with a batch size of 1 per GPU. Training time per epoch and inference time per slice were comparable to or slightly better than PromptMR. Training GPU memory consumption is 10 GB, which is 54% of the memory used by PromptMR.

For the CMRxRecon cardiac experiment, the data split setting used in PromptMR was used, which splits the 120 cases of the official CMRxRecon training dataset to 100 cases as the train set and 20 as the validation set. In this experiment, 60 cases in the official CMRxRecon validation dataset were used as the test set. Therefore, the number of training, validation, and test cases for this experiment was 100, 20, and 60, respectively. The number of training, validation, and test slices for Cine SAX data is 11964, 2364, and 7140, respectively. The number of training, validation, and test slices for Cine LAX data is 3000, and 576, and 1764, respectively. The number of training, validation, and test slices for Mapping T1w data is 4887, 954, and 2853, respectively. The number of training, validation, and test slices for Mapping T2w data is 1629, 318, and 951, respectively. The PromptMR was followed to balance the different types of training data and set the duplication ratio of T1w:T2w:LAX:SAX slices as 2:5:3:1. This resulted in a final training, validation, and test split of 38883, 3894, and 12708 slices, respectively. The experiment used the equally-spaced cartesian sampling masks, with acceleration factors of ×4, ×8 and ×10 during training. The center of the k-space, consisting of 24 phase encoding lines, was fully sampled. The evaluation was conducted using the code in the official CMRxRecon repository, with the modification that the background of the image was cropped. The model was trained for 11 epochs with a learning rate of 0.0002, dropped by a factor of 10 at the last epoch. Training took 2 days and 13 hours with a batch size of 1 per GPU. Training GPU memory consumption is 26 GB, which is 66% of the memory used by PromptMR.

For the fastMRI multi-coil knee experiment, the data split setting used in PromptMR was used, which split the 199 validation cases into 99 for validation and 100 for testing. Thus, the number of training, validation, and test cases is 973, 99, and 100, respectively, and the number of training, validation, and test slices is 34742, 3539, and 3596, respectively. The random cartesian sampling masks were used, with acceleration factors of ×4 and ×8 during training. The center of the k-space was fully sampled, corresponding to 8% and 4% of the phase encoding lines without acceleration for ×4 and ×8 accelerations, respectively. The evaluation was conducted using the code in the official fastMRI repository, with images center-cropped to 320×320. The model was trained for 45 epochs with a learning rate of 0.0001, dropped by a factor of 10 at epoch 35. Training took approximately 10 days with a batch size of 1 per GPU, which is 2 days slower than PromptMR.

It should be noted that the compared pretrained PromptMR model has an adjacent number of 3 with channel attention disabled for all Channel Attention Blocks (CAB) due to limited GPU memory. The model trained to implement the functionality described herein used an adjacent number of 5 with channel attention enabled. In this configuration, both models consume approximately 34 GB GPU memory during training.

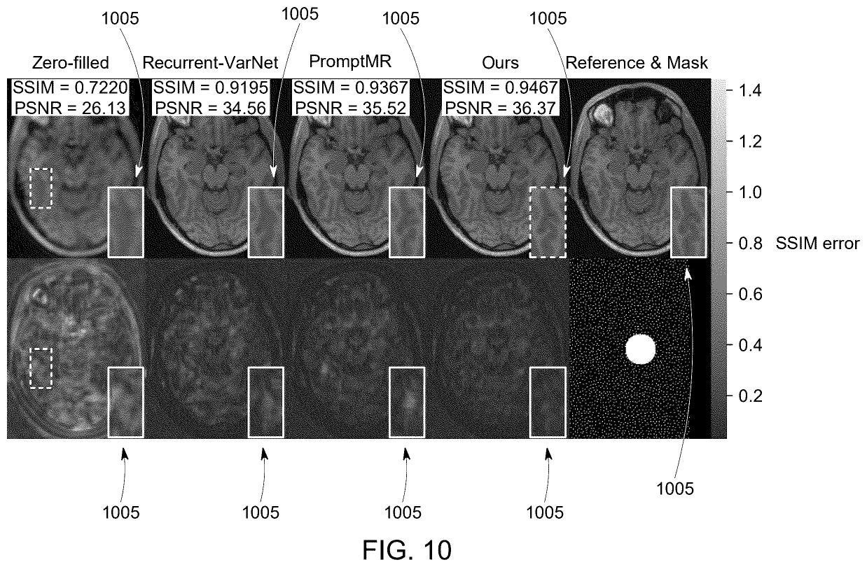

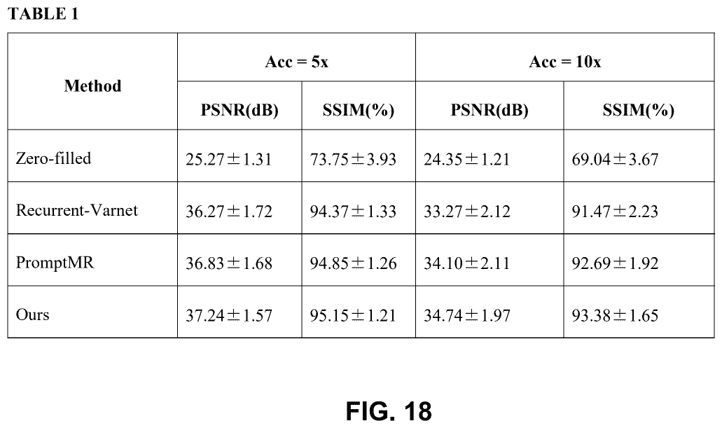

Table 1 (FIG. 18) presents the quantitative results for ×5 and ×10 acceleration factors on the Calgary-Campinas brain test set. The model implementing the methods and systems described herein (referenced as “Ours,” “Our model,” “Our method,” or “Our approach” herein) is compared with two other methods: Recurrent-VarNet and PromptMR. The quantitative comparison illustrated in Table 1 provides a mean±standard deviation of different MRI reconstruction methods on the Calgary-Campinas brain dataset under ×5 and ×10 acceleration. As illustrated in Table 1, our model outperformed these benchmarks, demonstrating improved performance. Qualitative results under ×10 acceleration are also illustrated in FIG. 10. In particular, FIG. 10 illustrates the reconstruction results and SSIM error maps of various reconstruction methods for the Calgary-Campinas brain imaging under ×10 acceleration factor. The boxes 1005 in FIG. 10 highlight the differences in the recovery of white and gray matter structures.

As illustrated in Table 1 and FIG. 10, while PromptMR achieves higher PSNR and SSIM values compared to Recurrent-VarNet, it exhibits less accurate reconstruction in the area highlighted by the box 1005. The highly undersampled k-space data makes the ill-posed reconstruction challenging at aliasing artifacts removal. While leveraging large-scale training data to learn the image priors can improve the reconstruction accuracy, Recurrent-VarNet learns a weaker prior, resulting in reconstructions that appear blurry. Conversely, PromptMR adopts a strong but overly biased prior, leading to sharper reconstructions but introducing incorrect structures. Our method, in contrast, successfully learns the appropriate prior, achieving a reconstruction that closely mirrors the ground truth in terms of structural accuracy.

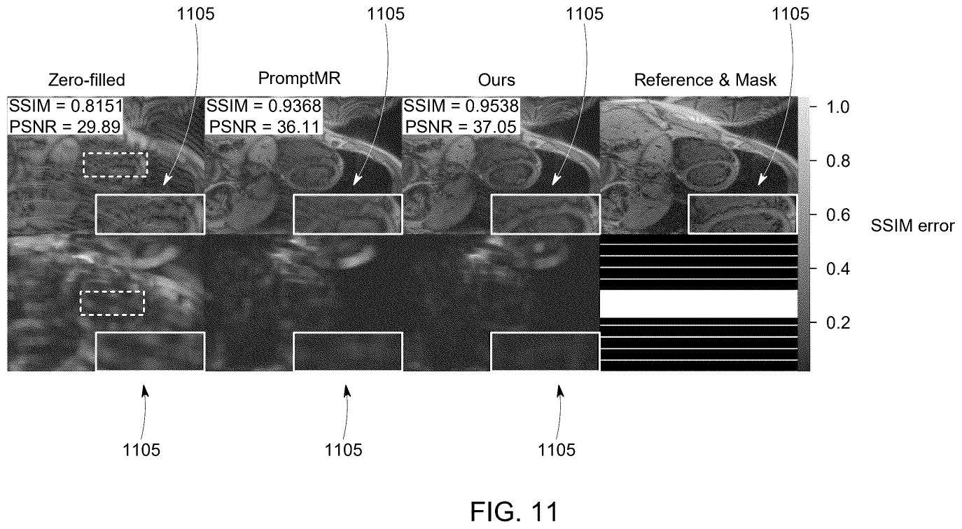

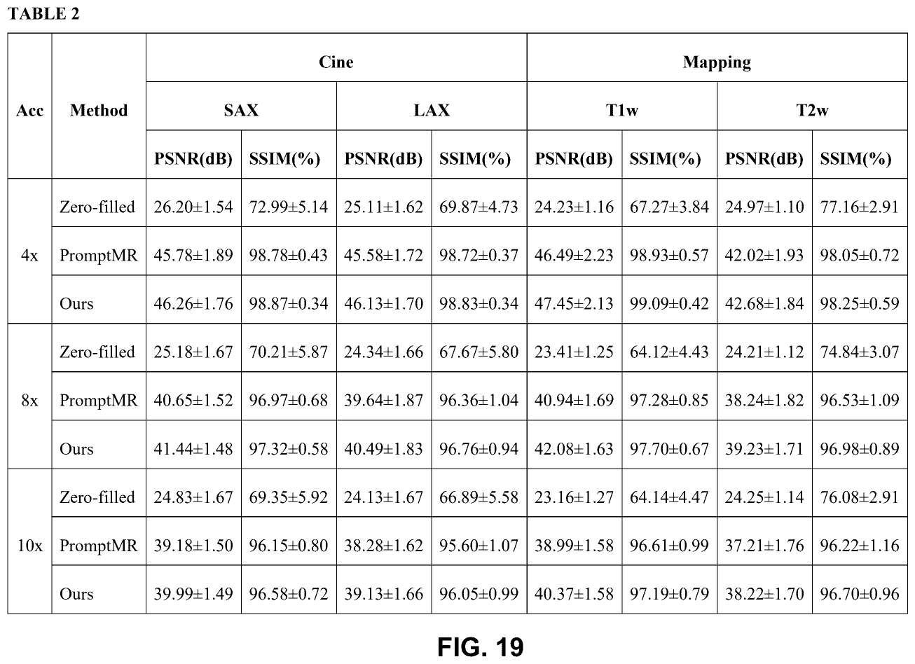

For the CMRxRecon cardiac experiments, our method was compared with PromptMR, the winning method of the MICCAI2023 CMRxRecon challenge, for ×4, ×8 and ×10 acceleration factors on the CMRxRecon cardiac test set. As set forth in Table 2 (FIG. 19), our method exhibits improved performance over PromptMR across different views and contrasts. In particular, Table 2 provides a quantitative comparison of PSNR/SSIM (mean±standard deviation) of different MRI reconstruction methods on the CMRxRecon cardiac dataset under ×4, ×8, and ×10 acceleration. Qualitative results under ×10 acceleration are also shown in FIG. 11. In particular, FIG. 11 illustrates reconstruction results and SSIM error maps of various methods for the CM-RxRecon cardiac T1-weighted imaging under ×10 acceleration factor. The boxes 1105 in FIG. 11 highlight the differences in the recovery of the interventricular septum. As illustrated in FIG. 11, the methods and systems described herein (“Ours” in FIG. 11) reconstructs fine details of the interventricular septum, highlighted in the box 1105, with significantly higher clarity than the PromptMR method, which is severely compromised by aliasing artifacts.

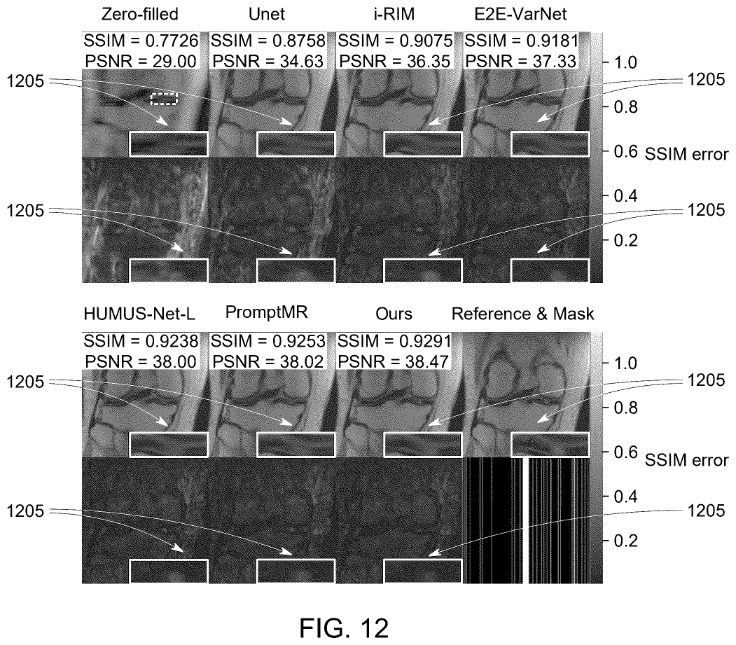

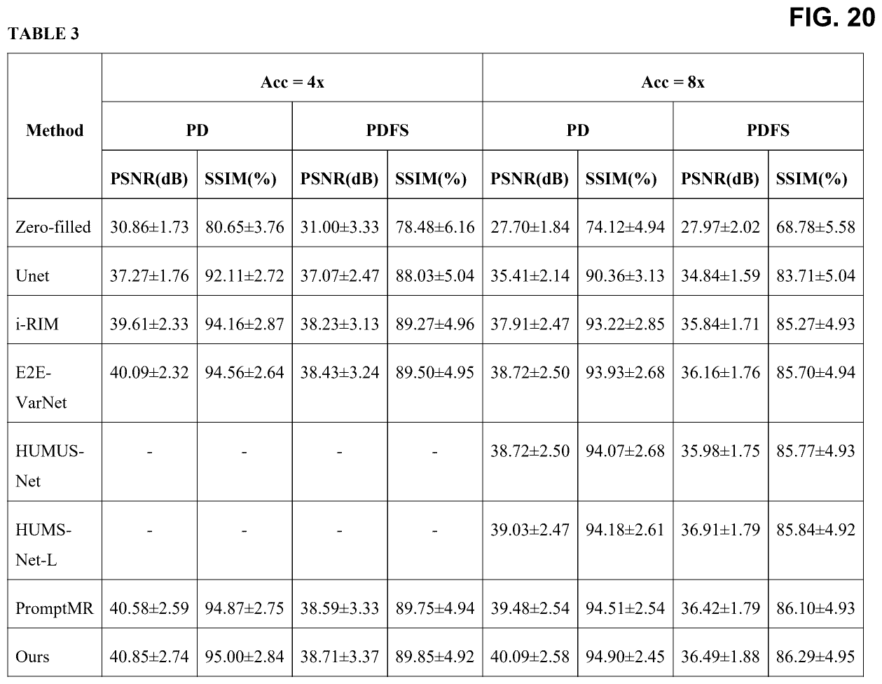

For the fastMRI knee experiment, the PSNR and SSIM were evaluation at acceleration factors of ×4 and ×8 on the fastMRI multi-coil knee test set. In particular, our method was compared to, among other reconstructions methods, HUMUS-Net-L and PromptMR. Table 3 (FIG. 20) provides a quantitative comparison of PSNR/SSIM (mean±standard deviation) of different MRI reconstruction methods on the fast MRI knee dataset under ×4 and ×8 acceleration. In Table 3, ‘PD’ and ‘PDFS’ denote proton density-weighted images without and with fat suppression, respectively. As illustrated in Table 3 (FIG. 20), our method achieves the best performance across all other competitive methods on this large-scale dataset. Qualitative results under ×8 acceleration are also illustrated in FIG. 12. In particular, FIG. 12 illustrates the reconstruction results and SSIM error maps of various reconstruction methods for the fastMRI multi-coil knee proton density (PD) imaging under ×8 acceleration. The boxes 1205 in FIG. 12 highlight the differences in the recovery of the meniscus region. The box 1205 in the reference image was annotated by radiologist from the fastMRI+ dataset to indicate the knee abnormality of meniscus tears.

As illustrated in FIG. 12, the methods and systems described herein (see “Ours” in FIG. 12) achieves a more detailed reconstruction of the meniscus region as shown in the box 1205, closely approximating the ground truth. Thus, the qualitative comparison demonstrates that our method is more robust in reconstructing abnormal knee regions for highly accelerated acquisition.

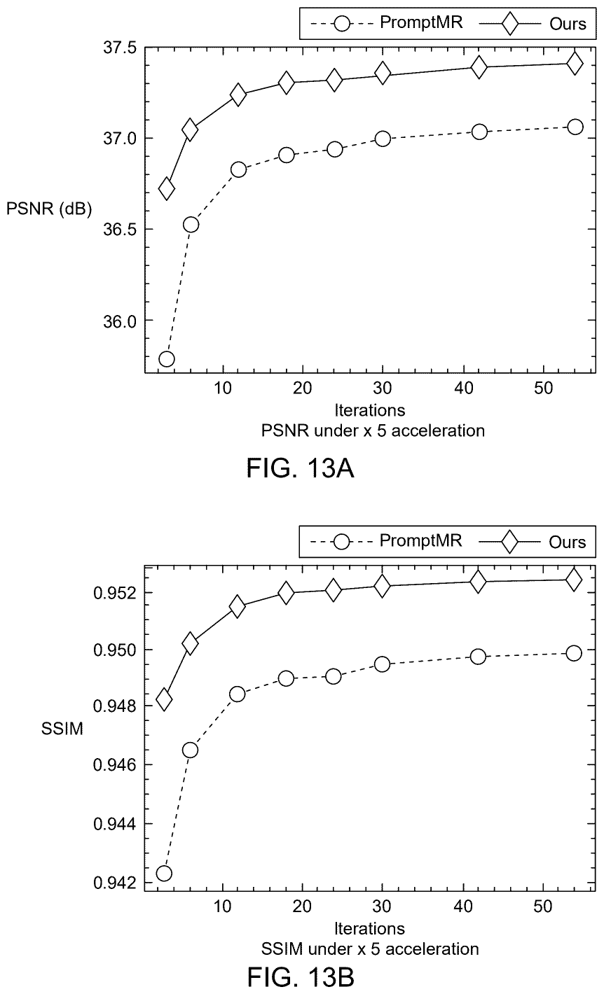

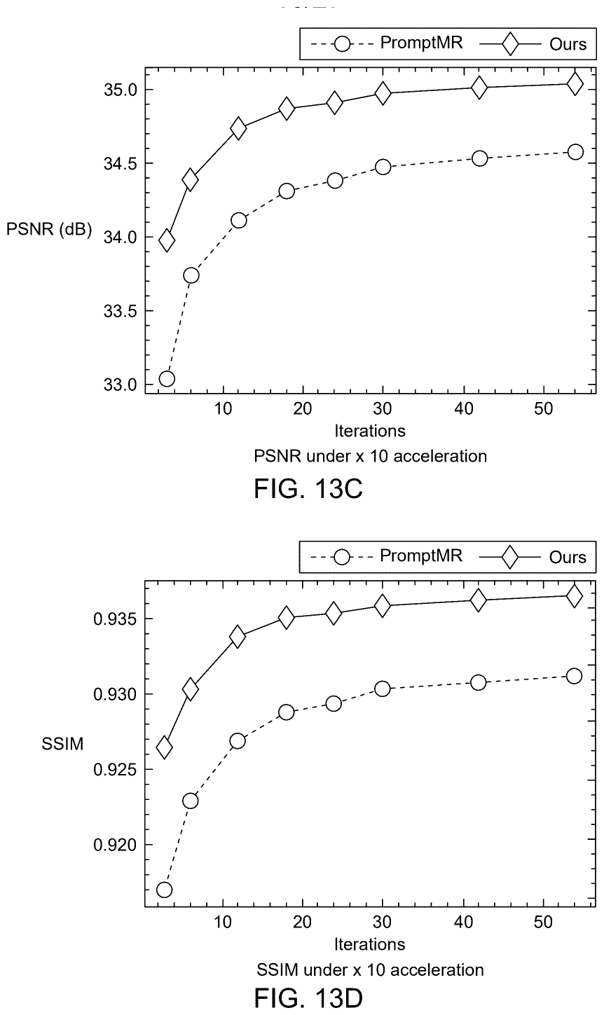

As noted above, the deep unrolled model (DUM) is an iterative MRI reconstruction method, and the methods and systems described herein accelerate the convergence speed of iterations in a DUM. For example, FIGS. 13A, 13B, 13C, and 13D provide a comparison of the systems and methods described herein (referenced as “Our method,” “Our model,” or “Ours”) with PromptMR on the convergence speed of iterations in a DUM for MRI reconstruction (e.g., using the Calgary-Campinas brain dataset). In this experiment, the DUMs were trained separately across a spectrum of iteration numbers, including 3, 6, 12, 18, 24, 30, 42, 54. As illustrated in FIGS. 13A, 13B, 13C, and 13D, our method converges faster than PromptMR, resulting in smaller iterations in a DUM for achieving the same reconstruction performance. For example, for under ×5 acceleration, with only 6 iterations, our method can achieve the same reconstruction performance as PromptMR with 54 iterations. Under ×10 acceleration, with 12 iterations, our method can achieve a better reconstruction performance than PromptMR with 54 iterations. These results demonstrate that our proposed method can significantly speed up the iteration convergence of DUM for highly undersampled MRI reconstruction.

### VII. Ablation Study

As noted above, it should be understood that the methods and systems described herein can be implemented using various setups and configurations and different setups and configurations may be used with different dataset or different clinical goals. Thus, any particular setups and configurations described herein should not be construed as being limiting.

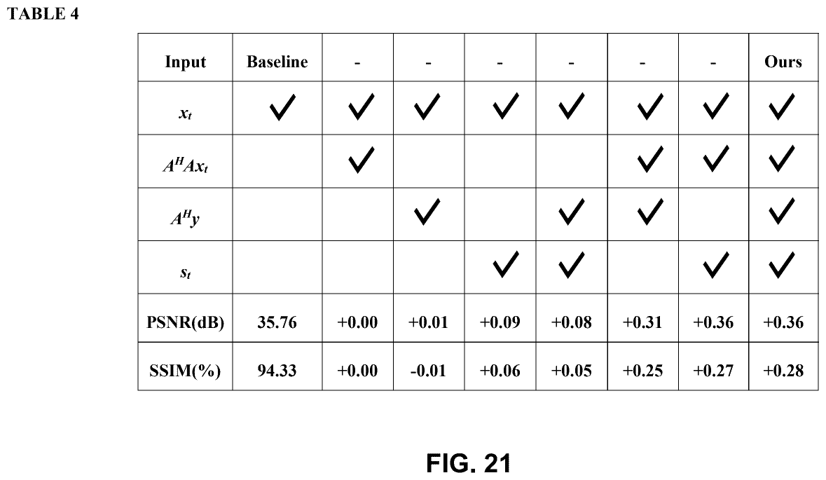

Various input combinations can be used with the CNN as described herein. For example, Table 4 (FIG. 21) illustrates an ablation of different input combinations of the CNN on the Calgary-Campinas brain dataset under ×10 acceleration.

The baseline network in each iteration only accepts the output from the last iteration xₜ as input, which is the setting for most unrolled models, such as E2E-VartNet and PromptMR. Our method takes additional input, A^{H}Axₜ, A^{H}y, and sₜ, which outperforms the baseline. As illustrated in Table 4, adding sₜ can improve the performance, as it serves as additional memory to track the progression of the reconstruction process. Adding A^{H}Axₜ together with A^{H}y also improves the gains, since, for example, the residual connection of two terms into the network can provide soft data consistency information to the model.

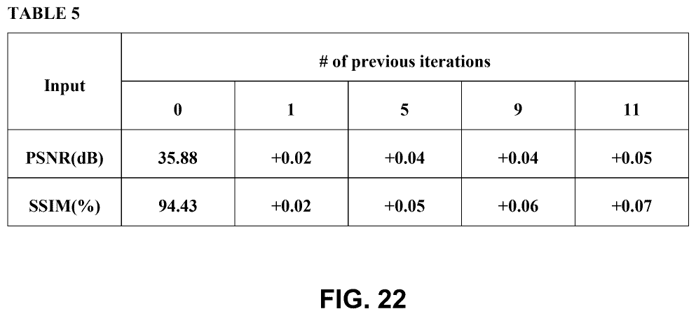

Table 5 (FIG. 22) illustrates the effective of incorporating different numbers of previous iteration results in the current iteration for multi-stage information fusion. As illustrated in Table 5, as the number increases, the reconstruction performance may increase (e.g., gradually).

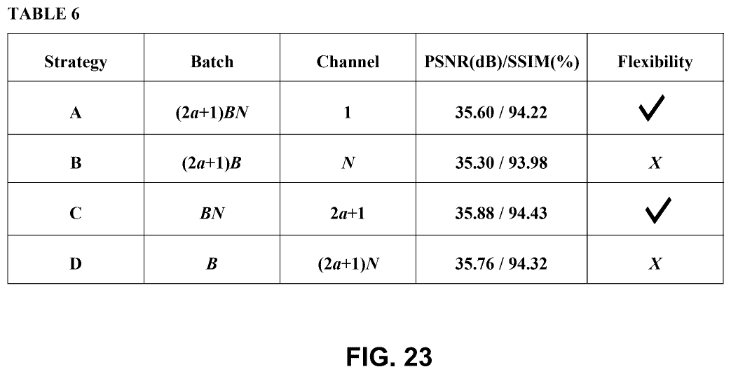

Table 6 (FIG. 23) illustrates a comparison of different strategies for sensitivity map estimation on the Calgary-Campinas brain dataset under ×10 acceleration. The “Batch” number in Table 6 is linearly related to memory consumption, and the “Flexibility” column indicates the ability to accept data with varying number of coils.

In particular, in Table 6 the impact of various strategies (see, e.g., strategies illustrated in FIG. 7) for sensitivity map estimation on both reconstruction performance and memory consumption. The ACS data input to the SME network is represented as a complex tensor with shape (B, 2a+1, N, h, w), where 2a+1 represents the adjacent number, N denotes the number of coils of each slice, and B indicates the batch size. As noted in Table 6, the batch size is linearly related to the memory consumption. As also illustrated in Table 6, Strategy A reshapes the tensor to a batch size of (2a+1)BN and a channel size of 1 for coil-by-coil estimation, and Strategy B concatenates the coils within each slice, reducing the batch size to (2a+1)B. In comparison, Strategy C concatenates the same coils from adjacent slices, decreasing the batch size to BN, and Strategy D combines all coils within a single batch. Note that only strategies A and C can be used for data with variable numbers of coils.

Accordingly, as illustrated in Table 6, Strategy C, which utilizes adjacent information, not only shows the best performance but also reduces memory consumption by a factor of 2a+1 compared to Strategy A. Also, even if Strategy B is illustrated as being the least effective in Table 6, ideally, since the coils within the same slice should be uncorrelated, this strategy does not impact performance. However, noise coupled across coils during acquisition may be amplified under this strategy, which may degrade SME performance.

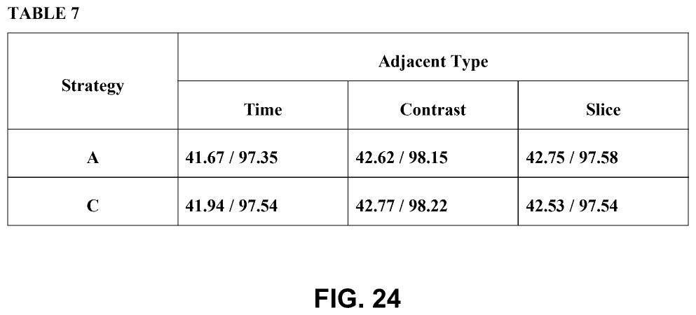

Table 7 (FIG. 24) illustrates a quantitative comparison of PSNR(dB)/SSIM (%) of different sensitivity map estimation strategies using different adjacent information types on the CMRxRecon cardiac dataset under ×10 acceleration.

As illustrated in Table 7, the types include temporal information in the cine LAX dataset, contrast information in the T1 mapping dataset, and slice information in the cine SAX dataset. Strategy C shows consistent improvement over Strategy A for adjacent types of time and contrast. However, the result of the slice adjacency experiment deviates from our expectations, as previously observed in the brain dataset in Table 6. This discrepancy is attributed to the considerable slice gap present in the cardiac dataset, which is 4.0 mm compared to no slice gap in the brain dataset. Accordingly, adjacent reconstruction may be beneficial when adjacent slices show high correlations but, in other implementations, it may detract from performance by introducing confounding facts for the network.

Accordingly, the methods and systems described herein improve the deep unrolled model for multi-coil MRI reconstruction through informative gradient-based learning and memory-efficient sensitivity map estimation. As noted above, the methods and systems are not limited to the specific setups and configurations described herein and may be used with other types of images and are not limited to MRI reconstruction.

Accordingly, as described above, systems and methods described herein provide a deep learning model for performing image reconstruction. Some examples include a deep neural network known as a “Deep Unrolled Model” (also referred to herein as a “DUM”), which operates by truncating and unrolling the conventional iterative reconstruction. The systems and methods described herein improve gradient and information flow across iteration stages in the DUM (e.g., used part of an image reconstruction, such as, for example, for Magnetic Resonance Images (MRIs)) and improve reconstruction quality, speed, and memory usage. While some examples described herein may be directed to MRI reconstruction, the systems and methods described herein may be used for other types of images, including, for example, ultrasound images, CAT scan images, as well as other imaging techniques that reconstruct images from sparse data (e.g., low resolution images). The methods and systems described herein are also not limited to imaging applications and may be used in other types of applications, such as, for example, signal processing and telecommunications, computational photography, seismic imaging and geophysics, and artificial intelligence (AI) based diagnostics.

For example, examples described herein provide an improved adaptive gradient algorithm, which is applied to a DUM to achieve self-adaptive dynamic learning rates adjusting for different spatial areas in an MRI. This approach provides a more flexible updating strategy for individual stages of the DUM. Systems and methods described herein may also provide (in addition to or separate from the described gradient improvement) a momentum technique used in gradient descent acceleration and may use a multi-stage and multi-level feature aggregation scheme to accelerate the iteration convergence of the DUM. Systems and methods described herein may also (in addition to or separate from the described gradient improvement, the described momentum technique, or both) use adjacent information to improve multi-coil image reconstruction by, for example, improving accuracy and memory efficiency of sensitivity map estimations.

For example, examples described herein provide methods for reconstructing images from undersampled measurement data using an iterative process. One method includes receiving undersampled data and generating an image estimate. The image estimate is refined through multiple iteration steps. For example, in each step, the method includes computing a data consistency term, generating a correction term using a machine learning model that considers both current and previous iteration information, and updating the image estimate based on the correction term, the data consistency term (e.g., as scaled), and a global learning rate corresponding to the iteration step. For example, updating the image estimate may include updating the image estimate by scaling the data consistency term using the global learning rate corresponding to the iteration step and adding the correction term to the scaled data consistency term. In some examples, the machine learning model may be an image processing model, and the output of the machine learning model may provide a pixel-wise correction for updating the image estimate.

Some examples described herein provide an iterative image reconstruction method using a multi-level neural network with an encoder-decoder structure. For each iteration step, the method concatenates current and previous image features at each decoder level. The method then generates combined features using an attention mechanism. The attention mechanism causes the neural network to focus on the more relevant information from different iterations. The image is reconstructed by iteratively updating the image estimate based on these combined features. Accordingly, the method provides a multi-stage and multi-level feature aggregation based on a momentum-accelerated gradient algorithm to enhance image reconstruction.

Some examples described herein provide a memory-efficient method for estimating sensitivity maps in image reconstruction. The method processes measurement data from a group of slices including multiple adjacent image slices simultaneously. The method extracts auto-calibration signal (ACS) data from these slices and uses a single forward pass through a sensitivity map estimation network to generate sensitivity maps for the group of slices at once. This approach results in a set of concatenated sensitivity maps for the target slice and one or more neighboring slices. By estimating maps for multiple slices in one operation, this method reduces computational overhead and memory usage compared to processing each slice individually, therefore leading to faster and more efficient image reconstruction. For example, in one non-limiting example, the measurement data is from N coils, and for each coil, a group of slices including 1 target slice and 2a adjacent slices is formed. For each coil, the method reduces the computational complexity from (2a+1) to 1. Accordingly, the method reduces the computational complexity from (2a+1) N to N for the multi-coil image reconstruction.

The systems and methods described herein are implemented via one or more computing systems. For example, image data may be input or otherwise accessed by one or more computing systems configured to perform image reconstruction as described herein. The computing systems are configured to perform image reconstruction and output reconstructed images (e.g., for display on one or more interfaces, storage to one or more memory modules, or a combination thereof).

The non-transitory computer-readable storage media may contain instructions that, when executed, cause the one or more electronic processors (included in the system resources) to perform various functions described herein. In various implementations, the system resources include one or more electronic processors, one or more graphics processing units, volatile computer memory, non-volatile computer memory, and/or one or more system buses interconnecting the components of the computing system. In some examples, the communications interface includes hardware and software components that communicate with other elements of the system. For example, the system resources may communicate with one or more imaging modalities and/or one or more image databases or repository via the communications interface.

In various implementations, the communications interface supports/may be implemented according to one or more serial communication standards, including RS-232, RS-485, Universal Asynchronous Receiver/Transmitter (UART), Inter-Integrated Circuit (I2C), Serial Peripheral Interface (SPI), and/or Universal Serial Bus (USB). In some examples, the communications interface supports communicating over a Controller Area Network (CAN).

In various implementations, the communications interface may connect to various networks. These can include mobile networks such as General Packet Radio Service (GPRS), Time-Division Multiple Access (TDMA), Code-Division Multiple Access (CDMA), Global System for Mobile Communications (GSM), Enhanced Data Rates for GSM Evolution (EDGE), High-Speed Packet Access (HSPA), Evolved High-Speed Packet Access (HSPA+), Long Term Evolution (LTE), Worldwide Interoperability for Microwave Access (WiMAX), and/or 5th-generation mobile networks (5G). The communications interface 204 may also connect to network types such as Internet Protocol (IP) networks, Wireless Application Protocol (WAP) networks, and/or IEEE 802.11 standards networks.

In some examples, the communications interface may connect to optical networks, local area networks (LANs), global communication networks like the Internet, and personal area networks (PANs) such as Bluetooth and Zigbee networks. In various implementations, the communications interface communicates with other devices via any of the previously described standards, networks, etc.

The storage may include one or more software applications, which one or more electronic processors and/or one or more graphics processing units of the system resources executes. The system resources may communicate with one or more human-machine interfaces, and operators can use the human-machine interfaces to interact with the running software applications.

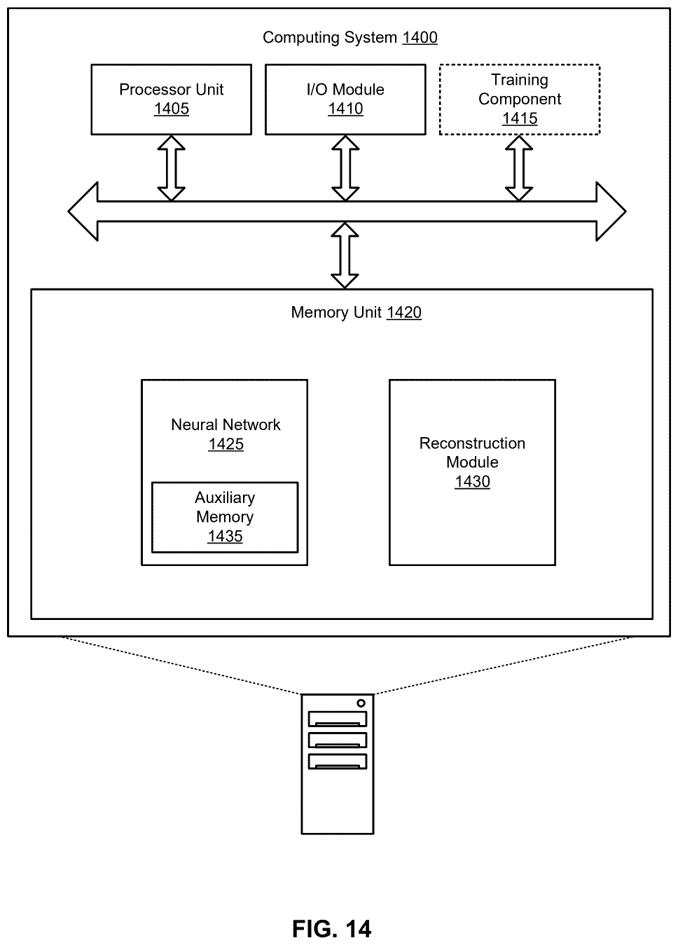

For example, FIG. 14 schematically illustrates a computing system 1400 according to some examples configured to perform the functionality described herein. As illustrated, the computing system 1400 includes, among other things, an electronic processor unit 1405, an input/output (I/O) module 1410, an optional training component 1415, and a memory unit 1420 (also referred to herein as memory 1420 or memory module 1420). The processor unit 1405, the I/O module 1410, the training component 1415, and the memory unit 1420 communicate over one or more control and/or data buses (e.g., an apparatus communication bus). FIG. 14 illustrates only one example of the computing system 1400, implemented as a single computing device or apparatus, such as a server, and it should be understood that the computing system 1400 may include more or fewer components than illustrated and may perform additional functions other than those described herein. For example, the computing system 1400 may include more than one processor unit 1405, more than one I/O module 1410, more than one training component 1415, more than one memory unit 1420, or a combination thereof. Also, the functionality described herein as being performed via the components stored in the memory unit 1420 may be combined and distributed in additional or fewer components, wherein a component may include a set of instructions (software) and/or data executable by the processor unit 1405. It should also be understood that the functionality described herein as being performed via the apparatus 300 may be distributed among multiple devices.

In some instances, the processor unit 1405 is implemented as a microprocessor with separate memory, such as the memory unit 1420. In other instances, the processor unit 1405 may be implemented as a microcontroller (with memory unit 1420 on the same chip). In other instances, the processor unit 1405 may be implemented using multiple processors. In addition, the processor unit 1405 may be implemented partially or entirely as, for example, a field-programmable gate array (FPGA), and application specific integrated circuit (ASIC), and the like and the memory unit 1420 may not be needed or be modified accordingly. In the example illustrated, the memory unit 1420 includes non-transitory, computer-readable memory that stores instructions that are received and executed by the processor unit 1405 to carry out functionality of described herein (i.e., the methods described herein as “our method,” “our model,” or “ours”). The memory unit 1420 may include, for example, a program storage area and a data storage area. The program storage area and the data storage area may include combinations of different types of memory, such as read-only memory and random-access memory.

The I/O module 1410 may include one or more ports (e.g., for receiving one or more wired cables or connections), transceivers, transmitters, receivers, or a combination thereof for communication with one or more devices or networks external to the computing system 1400. For example, in some examples, the I/O module 1410 communicates with one or more devices or networks providing access to MRI image data (i.e., an imaging modality, an image repository, or the like). The memory 1420 may store instructions and/or data received and executed by the processor unit 1405 to carry out the functionality described herein. For example, as illustrated in FIG. 14, in some examples, the memory unit 1420 stores a neural network 1425 (e.g., a convolutional neural network (CNN)) and a reconstruction module or component 1430 that, when executed by the processor unit 1405 performs the functionality described herein or a portion thereof. In some aspects, the neural network 1425 includes or accesses an auxiliary memory 1435 (referenced to as auxiliary memory sₜ above).

The optional training component 1415, which may be implemented as software stored in the memory unit 320 or stored in a separate memory unit of the system 1400, is configured to train the neural network 1425. In particular, the training component 1415 may be configured to initialize the neural network 1425, iteratively input training data (which may be stored in the training component 1415 or elsewhere) to the neural network, and adjust internal parameters (e.g., weights and biases) of the neural network until the neural network is considered trained or accurate (e.g., until a loss function is minimized). The training component 1415 is illustrated as being optional as, in some examples, the neural network 1425 may be initially trained by a separate system as the system 1400 using the neural network 1425, as trained, to perform image reconstruction as described herein.

The reconstruction module 1430 includes instructions executable by the processor unit 1405 to perform image (e.g., MRI) reconstruction as described herein. In particular, the reconstruction module 1430 is configured to perform DUM-based MRI reconstruction as described herein. In particular, the reconstruction module 1430 can be configured to implement the self-adaptive and momentum-accelerated gradient algorithm as described herein.

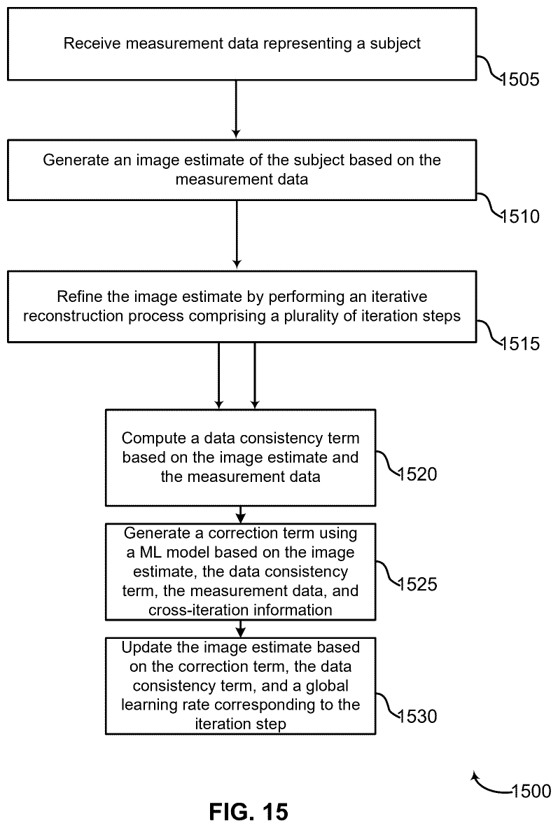

FIG. 15 is a flowchart illustrating a computer-implemented method 1500 for performing image reconstruction. The method 1500 may be performed via a computer system, such as the computing system 1400 of FIG. 14 to implement the functionality described herein.

At operation 1505, the method 1500 includes receiving measurement data representing a subject. As described herein, when the method is used for MRI image reconstruction, the measurement data may include undersampled measurements y in k-space. The k-space measurements include a combination of coil sensitivity maps S, the Fourier transform F, and an undersampling mask M (collectively referred to as A). It should be understood that the subject may be a human subject or another object imaged via an imaging modality, such as during an MRI scan.

At operation 1510, the method 1500 includes generating an image estimate of the subject based on the measurement data and, at operation 1515, the method 1500 includes refining the image estimate by performing an iterative reconstruction process comprising a plurality of iteration steps. Each iteration includes computing a data consistency term based on the image estimate and the measurement data (operation 1520), generating a correction term using a machine learning (ML) model based on the image estimate, the data consistency term, the measurement data, and cross-iteration information (at operation 1525), and updating the image estimate based on the correction term, the data consistency term, and a global learning rate corresponding to the iteration step (at operation 1530).

For example, with reference to the above equations and description (see, e.g., Section II), the image estimate at iteration t+1 (i.e., the refined image estimate) is generated by computing a data consistency term based on the original image estimate (i.e., estimate at iteration t(xₜ)) and the measurements y (i.e., A^{H}(Axₜ−y)), and a regularization or correction term based on image estimate (xₜ), the data consistency term (A^{H}(Axₜ−y) or A^{H}Axₜ and A^{H}y), the measurement data (y), and cross-iteration information (information stored in the auxiliary memory sₜ, serving as a hidden state to track the historical (pixel-wise) gradient information implicitly), as input into a neural network (CNNₜ). The data consistency term and the correction term are applied to the image estimate (xₜ) to update or refine the image estimate (xt+1). As described above, the refinement also uses a global (e.g., uniform for the image) learning rate (nr) corresponding to the iteration t.

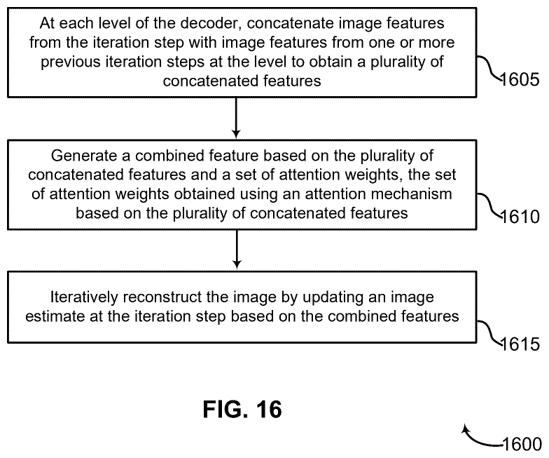

FIG. 16 is a flowchart illustrating a computer-implemented method 1600 for performing image reconstruction. The method 1600 may be performed via a computer system, such as the computing system 1400 of FIG. 14 to implement the functionality described herein.

The method 1600 may perform momentum-accelerated image reconstruction using a multi-level neural network (e.g., a convolutional neural network) including an encoder and a decoder, such as, for example, Unet. As illustrated in FIG. 16, the method 1600 includes, for each iteration step, (a) at each level of the decoder, concatenating image features from the iteration step with image features from one or more previous iteration steps at the level to obtain a plurality of concatenated features (at operation 1605), (b) generating a combined feature based on the plurality of concatenated features and a set of attention weights, the set of attention weights obtained using an attention mechanism based on the plurality of concatenated features (at operation 1610), and (c) iteratively reconstructing the image by updating an image estimate at the iteration step based on the combined features (at operation 1615). In some examples, the method also includes performing a dimensionality reduction on the plurality of concatenated features before obtaining the set of attention weights using the attention mechanism.

For example, with reference to the above equations and description (see, e.g., Section III), a momentum layer is inserted before the m-th level decoder layer, wherein the layer concatenates features at the current stage and feature from all previous iteration stages at the same level

$$( Concat ( {F}_{0}^{m} , … , {F}_{t}^{m} ) ) .$$

Following this concatenation, a 1×1 convolution layer (Conv_{1×1}) reduces the dimensionality, and a Channel Attention Block (CAB) is used to adaptively fuse the multi-stage information. A CAB sequentially applies attention mechanisms to refine feature maps. These attention mechanisms assign attention weights (e.g., scalar values) to highlight important features (e.g., important feature channels).

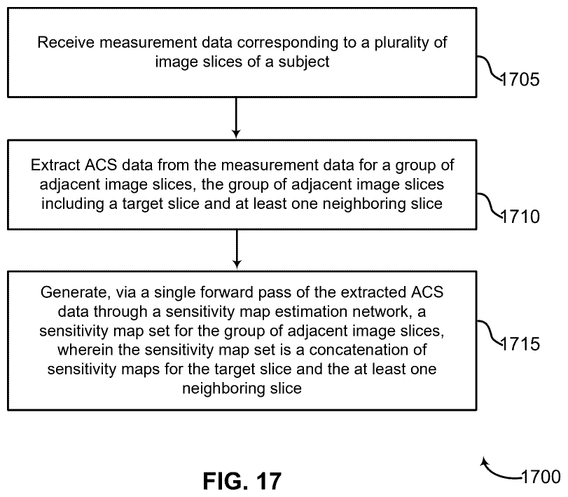

FIG. 17 is a flowchart illustrating a computer-implemented method 1700 for performing image reconstruction. The method 1700 may be performed via a computer system, such as the computing system 1400 of FIG. 14 to implement the functionality described herein.

The method 1700 performs memory-efficient sensitivity map estimation for multi-coil image reconstruction. As illustrated in FIG. 17, the method 1700 includes receiving measurement data corresponding to a plurality of image slices of a subject (at operation 1705). The method also includes extracting auto-calibration signal (ACS) data from the measurement data for a group of adjacent image slices, the group of adjacent image slices including a target slice and at least one neighboring slice (at operation 1710). The method 1700 further includes generating, via a single forward pass of the extracted ACS data through a sensitivity map estimation network, a sensitivity map set for the group of adjacent image slices, wherein the sensitivity map set is a concatenation of sensitivity maps for the target slice and the at least one neighboring slice (operation 1715).

For example, with reference to the above equations and description (see, e.g., Section IV), correlations between adjacent sensitivity maps can be used to reduce the number of forward passes and, in particular, sensitivity maps can be estimated using information spatially, temporally, and contrastively adjacent slices. In particular, a single coil sensitivity maps can be simultaneously estimated at all adjacent 2a+1 slices using information across these slices. In this way, the number of forward passes can be reduced from (2a+1) N to N. For example, as set forth in Equation 11 above, the estimation of the n-th sensitivity map set

$${S}_{adj}^{n}$$

is based on ACS data for the n-th coil ACS signal within all adjacent 2a+1 slices, wherein the set is the concatenation of the central (e.g., target) slice sensitivity map with its 2a-adjacent slice sensitivity maps of the n-th coil.

It should be understood that the generated image (e.g., generated via any of the methods described herein or any combination of thereof) may be transmitted or output in various reports, graphical user interfaces, messages, or the like after generation and refinement. For example, the generated and refined image estimate may be presented (e.g., within a graphical user interface) to a radiologist or other type of user for review and diagnosis. Alternatively or in addition, the generated and refined image estimate may be provided as input to other algorithms or model, such as, for example, a machine learned model for performing image diagnosis.

The descriptions included herein are merely illustrative in nature and does not limit the scope of the disclosure or its applications. The broad teachings of the disclosure may be implemented in many different ways. While the disclosure includes some particular examples, other modifications will become apparent upon a study of the drawings, the text of this specification, and the following claims. In the written description and the claims, one or more processes within any given method may be executed in a different order—or processes may be executed concurrently or in combination with each other—without altering the principles of this disclosure. Similarly, instructions stored in a non-transitory computer-readable medium may be executed in a different order—or concurrently—without altering the principles of this disclosure. Unless otherwise indicated, the numbering or other labeling of instructions or method steps is done for convenient reference and does not necessarily indicate a fixed sequencing or ordering.

It should also be noted that a plurality of hardware and software-based devices, as well as a plurality of different structural components may be utilized in various implementations. Aspects, features, and instances may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one instance, the electronic based aspects of the invention may be implemented in software (for example, stored on non-transitory computer-readable medium) executable by one or more processors. As a consequence, it should be noted that a plurality of hardware and software-based devices, as well as a plurality of different structural components may be utilized to implement the invention. For example, “control units” and “controllers” described in the specification can include one or more electronic processors, one or more memories including a non-transitory computer-readable medium, one or more input/output interfaces, and various connections (for example, a system bus) connecting the components.

Unless the context of their usage unambiguously indicates otherwise, the articles “a,” “an,” and “the” should not be interpreted to mean “only one.” Rather, these articles should be interpreted to mean “at least one” or “one or more.” Likewise, when the terms “the” or “said” are used to refer to a noun previously introduced by the indefinite article “a” or “an,” the terms “the” or “said” should similarly be interpreted to mean “at least one” or “one or more” unless the context of their usage unambiguously indicates otherwise.

It should also be understood that although certain drawings illustrate hardware and software located within particular devices, these depictions are for illustrative purposes only. In some examples, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable connections or links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all of the multiple determinations collectively. To reiterate, those electronic processors and processing may be distributed.

Spatial and functional relationships between elements—such as modules—are described using terms such as (but not limited to) “connected,” “engaged,” “interfaced,” and/or “coupled.” Unless explicitly described as being “direct,” relationships between elements may be direct or include intervening elements. The phrase “at least one of A, B, and C” should be construed to indicate a logical relationship (A OR B OR C), where OR is a non-exclusive logical OR, and should not be construed to mean “at least one of A, at least one of B, and at least one of C.” The term “set” does not necessarily exclude the empty set. For example, the term “set” may have zero elements. The term “subset” does not necessarily require a proper subset. For example, a “subset” of set A may be coextensive with set A, or include elements of set A. Furthermore, the term “subset” does not necessarily exclude the empty set.

In the figures, the directions of arrows generally demonstrate the flow of information—such as data or instructions. The direction of an arrow does not imply that information is not being transmitted in the reverse direction. For example, when information is sent from a first element to a second element, the arrow may point from the first element to the second element. However, the second element may send requests for data to the first element, and/or acknowledgements of receipt of information to the first element. Furthermore, while the figures illustrate a number of components and/or steps, any one or more of the components and/or steps may be omitted or duplicated, as suitable for the application and setting.

Additionally, operations (such as processes, decisions, inputs, outputs, actions, messages, interactions, events, and/or any other operations) shown in the flowcharts and/or message sequence charts may be illustrated once each and in a particular order in the drawings. However, in various implementations, the operations may be reordered and/or repeated as may be suitable. In some examples, different operations may be performed in parallel, as may be appropriate.

The term computer-readable medium does not encompass transitory electrical or electromagnetic signals or electromagnetic signals propagating through a medium-such as on an electromagnetic carrier wave. The term “computer-readable medium” is considered tangible and non-transitory. The functional blocks, flowchart elements, and message sequence charts described above serve as software specifications that can be translated into computer programs by the routine work of a skilled technician or programmer.

What is claimed is:

1. A computer-implemented method for image reconstruction, comprising:
receiving measurement data representing a subject;
generating an image estimate of the subject based on the measurement data; and
refining the image estimate by performing an iterative reconstruction process comprising a plurality of iteration steps, each iteration step comprising:
computing a data consistency term based on the image estimate and the measurement data;
generating a correction term using a machine learning model based on the image estimate, the data consistency term, the measurement data, and cross-iteration information; and
updating the image estimate based on the correction term, the data consistency term, and a global learning rate corresponding to the iteration step.

2. The computer-implemented method of claim 1, wherein the measurement data includes magnetic resonance imaging (MRI) data.

3. The computer-implemented method of claim 2, wherein the measurement data includes undersampled measurements.

4. The computer-implemented method of claim 1, wherein the cross-iteration information tracks gradient information over the plurality of iteration steps.

5. The computer-implemented method of claim 4, wherein the cross-iteration information tracks pixel-wise gradient information over the plurality of iteration steps.

6. The computer-implemented method of claim 1, wherein updating the image estimate includes scaling the data consistency term using the global learning rate corresponding to the iteration step and adding the correction term to the scaled data consistency term.

7. The computer-implemented method of claim 1, wherein the machine learning model includes a convolution neural network.

8. Non-transitory computer-readable medium storing instructions executable by one or more electronic processors to perform a set of functions, the set of functions comprising:
receiving measurement data representing a subject;
generating an image estimate of the subject based on the measurement data; and
refining the image estimate by performing an iterative reconstruction process comprising a plurality of iteration steps, each iteration step comprising:
computing a data consistency term based on the image estimate and the measurement data;
generating a correction term using a machine learning model based on the image estimate, the data consistency term, the measurement data, and cross-iteration information; and
updating the image estimate based on the correction term, the data consistency term, and a global learning rate corresponding to the iteration step.

9. The non-transitory computer-readable medium of claim 8, wherein the measurement data includes magnetic resonance imaging (MRI) data.

10. The non-transitory computer-readable medium of claim 9, wherein the measurement data includes undersampled measurements.

11. The non-transitory computer-readable medium of claim 8, wherein the cross-iteration information tracks gradient information over the plurality of iteration steps.

12. The non-transitory computer-readable medium of claim 11, wherein the cross-iteration information tracks pixel-wise gradient information over the plurality of iteration steps.

13. The non-transitory computer-readable medium of claim 8, wherein updating the image estimate includes scaling the data consistency term using the global learning rate corresponding to the iteration step and adding the correction term to the scaled data consistency term.

14. The non-transitory computer-readable medium of claim 8, wherein the machine learning model includes a convolution neural network.

15. A computing system for image reconstruction, comprising:
a memory storing a machine learning model, cross-iteration information, and a reconstruction module;
a processor unit configured to execute the reconstruction module to:
receive measurement data representing a subject;
generate an image estimate of the subject based on the measurement data; and
refining the image estimate by performing an iterative reconstruction process comprising a plurality of iteration steps, each iteration step comprising:
computing a data consistency term based on the image estimate and the measurement data;
generating a correction term using the machine learning model based on the image estimate, the data consistency term, the measurement data, and cross-iteration information; and
updating the image estimate based on the correction term, the data consistency term, and a global learning rate corresponding to the iteration step.

16. The computing system of claim 15, wherein the measurement data includes magnetic resonance imaging (MRI) data.

17. The computing system of claim 15, wherein the cross-iteration information tracks gradient information over the plurality of iteration steps.

18. The computing system of claim 17, wherein the cross-iteration information tracks pixel-wise gradient information over the plurality of iteration steps.

19. The computing system of claim 15, wherein updating the image estimate includes scaling the data consistency term using the global learning rate corresponding to the iteration step and adding the correction term to the scaled data consistency term.

20. The computing system of claim 15, wherein the machine learned model includes a convolution neural network.
